(19) United States
(12) Patent Application Publication
(10) Pub. No.: US 2024/0429257 A1
(43) Pub. Date: Dec. 26, 2024

(54) METALENS FOR NEAR INFRARED PHOTODETECTOR

(71) Applicant: Taiwan Semiconductor Manufacturing Company, Ltd., Hsinchu (TW)

(72) Inventors: Yi-Hsuan Wang, Hsinchu City (TW); Cheng Yu Huang, Hsinchu (TW); Chun-Hao Chuang, Hsinchu City (TW); Keng-Yu Chou, Kaohsiung City (TW); Wen-Hau Wu, New Taipei City (TW); Wei-Chieh Chiang, Yuanlin Township (TW); Chih-Kung Chang, Zhudong Township (TW)

(21) Appl. No.: 18/341,205

(22) Filed: Jun. 26, 2023

(51) Int. Cl. H01L 27/146

(52) U.S. Cl. CPC H01L 27/14627; H01L 27/14634; H01L 27/14649; H01L 27/14685; H01L 27/1469; G02B 1/002

(57) ABSTRACT

An image sensing device includes a germanium sensor within a semiconductor body and a metalens formed in the back side of the semiconductor body. The metalens is structured to focus infrared light on the germanium sensor and may have a lower profile than an equivalent microlens. Optionally, the metalens is combined with a microlens to achieve a desired focal length. The metalens, or the metalens in combination with a microlens, overcomes a manufacturing process limitation on the focal length of the microlens, which in turn eliminates the need for, or reduces the thickness of, a spacer between the microlens and the germanium sensor. Eliminating the spacer or reducing its thickness improves the angular response of the image sensing device.

### BACKGROUND

Integrated circuits (ICs) comprising image sensors are used in a wide range of modern-day electronic devices such as cameras and cell phones. Complementary metal-oxide semiconductor (CMOS) image sensors (CISs) have become popular. Compared to charge-coupled devices (CCDs), CISs are increasingly favored due to low power consumption, small pixel size, fast data processing, and low manufacturing cost. As the pixel sizes are made smaller, manufacturing becomes increasingly difficult as does limiting crosstalk between pixels.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional side view of an image sensing device according to some embodiments.

FIG. 2 illustrates a plan view of an image sensing device according to some embodiments and may correspond with the image sensing device of FIG. 1.

FIG. 3 illustrates a plan view of an image sensing device according to some other embodiments and may correspond with the image sensing device of FIG. 1.

FIG. 4 illustrates a plan view of an image sensing device according to some other embodiments.

FIGS. 5-8 illustrate cross-sectional side views of image sensing devices according to various other embodiments.

FIGS. 9-22 are a series of cross-sectional view illustrations exemplifying some embodiments of a method of forming an image sensing device.

FIG. 23 provides a flow chart illustrating some embodiments of a method of forming an image sensing device.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Manufacturing process constraints limit the focal length for a microlens of the type used to focus electromagnetic radiation on a photosensitive structure in a CMOS image sensing device. A spacer or like structure interposed between the microlens and the photosensitive structure can increase the optical path length so that the incoming electromagnetic radiation is able to narrow from the spot size of the microlens to the spot size of the photosensitive structure within the focal length constraint. A shortcoming of this approach is that increasing the optical path length worsens the angular response. The angular response relates to a range of angles of incidence over which incoming electromagnetic radiation is effectively captured by the photosensitive structure.

Some aspects of the present disclosure relate to an image sensing device in which a metalens is interposed between a microlens and a photosensitive structure. The metalens combines with the microlens to reduce the focal length allowing the spacer height to be reduced or the spacer to be eliminated altogether. The metalens has an array of nanostructures, which are structures smaller than the wavelength of the electromagnetic radiation that is being focused. The nanostructures systematically vary in one or more of width, shape, spacing, and height in a pattern organized around a center of the metalens. Light passing through the metalens is delayed by the nanostructures. The delay varies in relation to the variation in the nanostructures so as to produce a lens effect and focus incident electromagnetic radiation on the photosensitive structure. In some embodiments, the variations occur in a pattern that repeats from a center to an edge of the metalens.

Some aspects of the present disclosure relate to an image sensing device that has a metalens positioned to focus electromagnetic radiation on a photosensitive structure. That metalens may work in conjunction with a microlens or in lieu of a microlens. In some embodiments, the metalens is effective for a wavelength in the near infrared range. In some embodiments, the photosensitive structure is within a semiconductor body and the nanostructures are formed by a surface of the semiconductor body. In some embodiments, the semiconductor body is silicon. In some embodiments photosensitive structure is a germanium sensor that comprises a germanium structure within the semiconductor body. The germanium structure provides the photosensitive structure for a germanium sensor. In some embodiments, the image sensing device is designed for illumination from the back side of the semiconductor body, has the germanium structure proximate the front side of the semiconductor body, and the metalens is effective for focusing the electromagnetic radiation having a wavelength in the near infrared range on the germanium structure.

In some embodiments, the nanostructures of the metalens are formed of a first optical material and a second optical material fills in and around the nanostructures. The first optical material may be the semiconductor body. The first optical material and the second optical material have different refractive indexes. In some embodiments, the second optical material has a refractive index of at least 2.0. A large difference between the refractive index of the first material and the refractive index of the second material increases the effectiveness of the metalens. A smaller difference between the refractive index of the first material and the refractive index of the second material may allow reflections to be reduced.

In some embodiments, the nanostructures are pillars of the first optical material. In some embodiments, the nanostructures are holes in the first optical material, the holes being filled by pillars of the second optical material. In some embodiments, the nanostructures are rings of the first optical material interleaved with rings of the second optical material. Holes, pillars, ring-shaped ridges, and ring-shaped trenches are structures that lend themselves to manufacturing on a small scale.

Some aspects of the present disclosure relate to an image sensing device that has a lens formed in a semiconductor body that contains a photosensitive structure. In some embodiments, the lens is formed in a back side surface of the semiconductor body and the photosensitive structure is illuminated from the back side. The lens may be shallower than a spherical lens of equivalent focal length. In some embodiments, the back side surface of the lens is neither purely convex nor purely concave but has a plurality of nanostructures so that the surface has peaks and valleys. In some embodiments, the lens comprises nanostructures that vary across the lens surface in the pattern of a periodic function. In some embodiments, the pattern repeats across the lens. The nanostructures are subwavelength structures with respect to a near infrared wavelength. In some embodiments, the lens is a metalens. In some embodiments, the photosensitive structure is disposed within the semiconductor body proximate its front side. In some embodiments, the semiconductor body is silicon and the photosensitive structure is germanium disposed within the semiconductor body.

Some aspects of the present disclosure relate to a method of forming an image sensing device. The method includes forming a photodetecting region in the front side of a semiconductor body. In some embodiments, forming the photodetecting region includes etching a hole in a semiconductor body and epitaxially growing a second semiconductor within the hole. In some embodiments, the semiconductor body is silicon, and the second semiconductor is germanium. The semiconductor body is flipped over and thinned. The back side of the semiconductor body is patterned to define the nanostructures of a metalens positioned to focus electromagnetic radiation from the back side onto the second semiconductor. A layer of an optical material is deposited over the nanostructures filling in and around the nanostructures. In some embodiments, an antireflective coating is formed over the layer of optical material. In some embodiments, a spacer is formed above the layer of optical material. In some embodiments, a microlens is formed over the metalens. In some embodiments, a second metalens is formed over the metalens.

Some other aspects of the present disclosure relate to a variation of the foregoing method. In this variation, a first layer of optical material that is over the back side of the semiconductor body is patterned to form the nanostructures. A second layer of optical material having a different refractive index from the first layer of optical material is deposited over the first layer of optical material to complete the formation of the metalens.

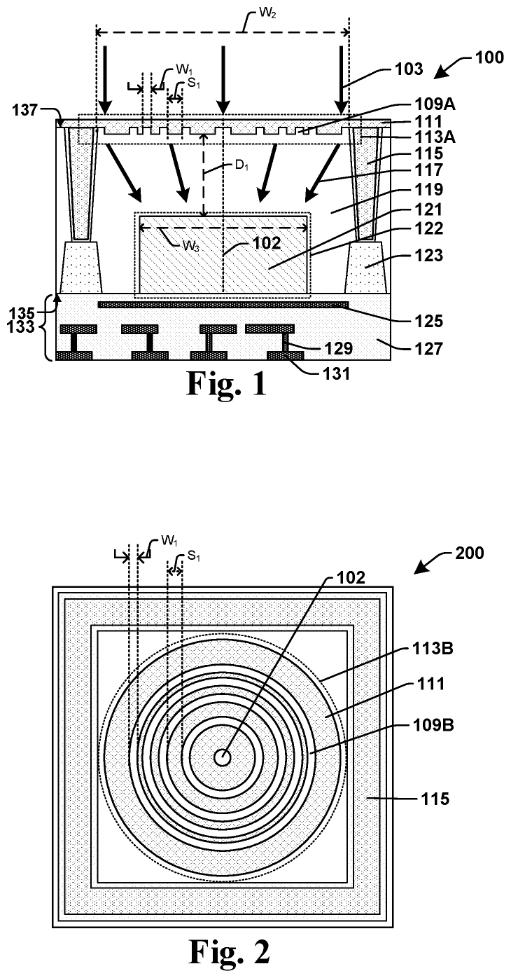

FIG. 1 illustrates a cross-sectional view of an image sensing device 100 according to some aspects of the present disclosure. The image sensing device 100 includes a photodetecting region 122 within a semiconductor body 119. The semiconductor body 119 has a front side 135 and a back side 137. The photodetecting region 122 comprises a photosensitive structure 121 within the semiconductor body 119 proximate the front side 135. A metalens 113A is formed in the back side 137. A metal interconnect 133 may be disposed on the front side 135.

The photodetecting region 122 may be one pixel in an array. Isolation structures such as a back side deep trench isolation structure 115 and shallow trench isolation structures 123 may provide electrical isolation that suppresses crosstalk between adjacent pixels. The photosensitive structure 121 may have a relatively high absorptivity for infrared light whereas the semiconductor body 119 may have a relatively low absorptivity for infrared light. The photodetecting region 122 may comprise a PN diode (not shown). In some embodiments, the PN diode is disposed within the photosensitive structure 121. In some embodiments, the PN diode is formed between the photosensitive structure 121 and the semiconductor body 119. The photodetector may comprise transistors and other additional structures (not shown) such as a floating diffusion region, a select gate, a transfer gate, a reset gate, and the like. These structures may be formed in or on the semiconductor body 119. Optionally, some of these structures are provided on a second substrate (not shown) and connected to the photodetecting region 122 through wires 131 and vias 129 of the metal interconnect 133.

Incoming electromagnetic radiation 103 incident on the metalens 113A is focused by the metalens 113A into converging electromagnetic radiation 117. The converging electromagnetic radiation 117 converges onto the photosensitive structure 121. The converging electromagnetic radiation 117 generates electron-hole pairs within the photosensitive structure 121. An electric field generated by a PN diode or the like separates the electrons and holes before they recombine so that resulting charges may be accumulated and detected. A reflector 125 may reflect some of the converging electromagnetic radiation 117 that goes through or past the photosensitive structure 121 back onto the photosensitive structure 121 so as to increase the efficiency of the photodetecting region 122.

The metalens 113A comprises nanostructures 109A that are provided by the back side 137 of the semiconductor body 119. The nanostructures 109A have a spacing S₁ that varies in relation to distance from the center 102. The center 102 is a center of the photosensitive structure 121 and of the metalens 113A. In some embodiments, the variation comprises a monotonically increasing or decreasing sequence. In some embodiments, the sequence repeats. In some embodiments, the nanostructures 109A are symmetric about the center 102. In some embodiments, the nanostructures 109A each have a width W₁ with the possible exception of a nanostructure 109A on the center 102.

In some embodiments, the widths W₁ of the nanostructures 109A are less than about 1000 nm. In some embodiments, the widths W₁ of the nanostructures 109A are in the range from about 10 nm to about 500 nm. In some embodiments, the spacings S₁ between adjacent nanostructures 109A are less than about 1000 nm. In some embodiments, the spacings S₁ are in the range from about 10 nm to about 500 nm. In some embodiments, a string of nanostructures 109A (a set of nanostructures 109A in a row along a line segment) has three or more distinct spacings in monotonically increasing or decreasing order. In some embodiments, the string of nanostructures 109A has five or more distinct spacings in monotonically increasing or decreasing order. In some embodiments, a string of nanostructures 109A has a sequence of monotonically increasing or decreasing spacings S₁ that repeats twice of more between the center 102 and an edge of the metalens 113A. In some embodiments, a string of the nanostructures 109A has a sequence of monotonically increasing or decreasing spacings S₁ that repeats three of more times between the center 102 and the edge of the metalens 113A.

An optical material layer 111 is disposed over the back side 137 and fills gaps between adjacent nanostructures 109A. The optical material layer 111 may be any transparent material that has a refractive index that is different from that of the semiconductor body 119. In some embodiments, the optical material layer 111 has a refractive index that is less than that of the semiconductor body 119. In some embodiments, the difference in refractive index is in the range from about 0.3 to about 2. In some embodiments, the difference in refractive index is in the range from about 1.0 to about 1.5. Increasing the difference in refractive index reduces the focal length but may also increase reflection. In some embodiments, the optical material layer 111 is an oxide such as silicon dioxide (SiO₂), tantalum oxide (Ta₂O₅), or the like. Additional dielectric layers (not shown) may be disposed over the optical material layer 111 to reduce reflections, to improve electrical isolation, to provide wavelength filtering, or to provide encapsulation.

The metalens 113A provides one example of a metalens according to the present disclosure. More generally, a metalens according to the present disclosure comprises nanostructures that vary in relation to distance from the center 102. The variations may be in any of the size, spacing, shape, or depth of the nanostructures. The variation in nanostructures relates to a variation in an effective refractive index experienced by electromagnetic radiation passing through the metalens. The composite medium that includes the nanostructures and whatever medium fills gaps between the nanostructures provides an effective refractive index that varies in a position dependent manner so that the overall variation creates the focusing effect of a lens. The variation in effective refractive index relates to a variation in phase shift. The variations are structures so that the phase shift correlates with the formula:

$$φ ( x ) = \frac{- 2 π}{λ} ( \sqrt{{x}^{2} + {f}^{2}} - f )$$

where φ(x) is the phase shift, x is the distance from the center 102, λ is the wavelength of electromagnetic radiation being focused, and f is the focal length. In some embodiments, the metalens provides the desired focal length f for a wavelength in the near infrared range. The near infrared range is from about 800 nm to about 2,500 nm. The desired focal length f may be realized for a wavelength of, for example, about 1000 nm.

With reference to FIG. 1, the focal length f relates to the width W₂ of the metalens 113A, the width W₃ of the photosensitive structure 121, and the distance D₁ from the metalens 113A to the photosensitive structure 121. For the metalens 113A to reduce the spot size of incident electromagnetic radiation to the spot size of the photosensitive structure 121, the focal length should be about:

$$f = \frac{{D}_{1}}{1 - \frac{{W}_{3}}{{W}_{2}}}$$

In some embodiments, D₁ is in the range from about 1 μm to about 5 μm. In some embodiments, Di is in the range from about 2 μm to about 3 μm. In some embodiments, the ratio of W₃ to W₂ is in the range from about 0.2 to about 0.8. In some embodiments, the ratio of W₃ to W₂ is in the range from about 0.4 to about 0.6, e.g., about 0.5. An initial design for a metalens that is based on a mathematical formula may be refined with computer simulation.

FIG. 2 illustrates a plan view 200 showing a metalens 113B that may correspond to the metalens 113A of FIG. 1. The metalens 113B has ring-shaped nanostructure 109B. The optical material layer 111 fills spaces between the ring-shaped nanostructure 109B to complete the metalens 113B. The ring-shaped nanostructure 109B are provided by ridges on the back side 137 of the semiconductor body 119 (see FIG. 1). The spacing between the ring-shaped nanostructure 109B progressively decreases through a string of four ring-shaped nanostructure 109B. The pattern begins to repeat at the center and edge of the metalens 113B. It should be appreciated that there may be many more ring-shaped nanostructures 109B for each photodetecting region 122 in an array than are shown in the drawings. The drawings show smaller numbers of nanostructures for ease of illustration.

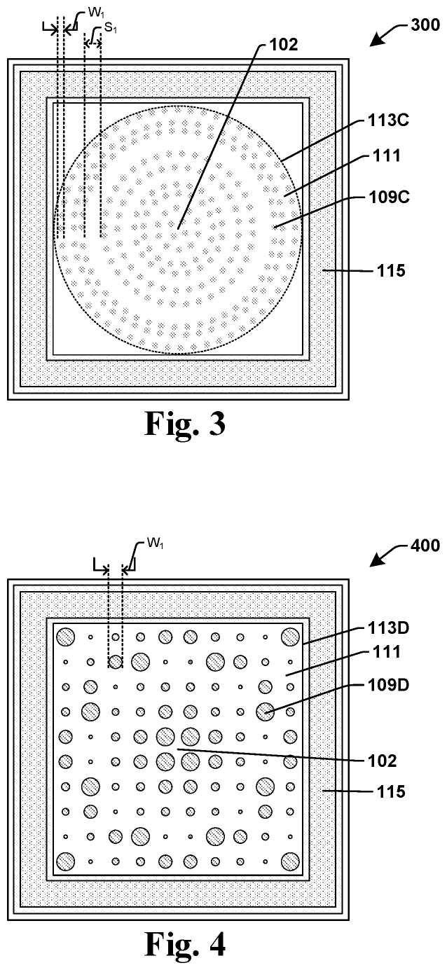

FIG. 3 illustrates a plan view 300 showing a metalens 113C, which is another metalens that may correspond to the metalens 113A of FIG. 1. The metalens 113C has column-shaped nanostructures 109C formed by the semiconductor body 119 (see FIG. 1). The column-shaped nanostructures 109C may have diameters that equal the width W₁. The column-shaped nanostructures 109C are arranged in concentric rings about the center 102. The concentric rings have the spacing S₁, which undergoes a periodic variation. The column-shaped nanostructures 109C protrude into the optical material layer 111. A metalens according to an alternative embodiment comprises holes (not shown) in semiconductor body 119. In this alternative embodiments, columns of the optical material layer 111 protrude into the holes. More generally, for each nanostructure shape illustrated in the present disclosure there is an inverse nanostructure shape that may be used to provide an alternative embodiment.

FIG. 4 illustrates a plan view 400 for a metalens 113D, which is a metalens that may be used in place of the metalens 113A of FIG. 1. The metalens 113D has column-shaped nanostructure 109D. The widths W₁ of the column-shaped nanostructures 109D vary in relation to distance from the center 102 so as to provide the focusing effect of the metalens 113D. In some embodiments, the column-shaped nanostructure 109D are evenly spaced as shown in the illustration. In some embodiments, the column-shaped nanostructure 109D have a variable spacing that contributes to the focusing effect. For example, the column-shaped nanostructure 109D may become more widely spaced in conjunction with becoming narrower.

FIG. 5 illustrates a cross-sectional view of an image sensing device 500 according to another embodiment. The image sensing device 500 is like the image sensing device 100 of FIG. 1 except that the image sensing device 500 has a metalens 113E. The metalens 113E has nanostructures 109E provided by holes or ring-shaped trenches in the back side 137. The nanostructures 109E have a variation in depth that makes the metalens 113E effective to focus incoming electromagnetic radiation 103, redirecting it into electromagnetic radiation 117 that converges on the photosensitive structure 121.

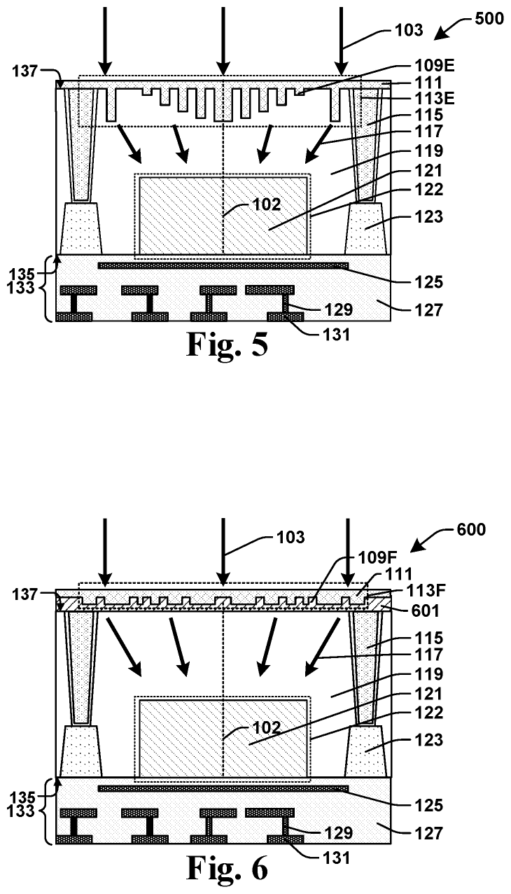

FIG. 6 illustrates a cross-sectional view of an image sensing device 600 according to another embodiment. The image sensing device 600 is like the image sensing device 100 of FIG. 1 except that the image sensing device 600 has a metalens 113F. The metalens 113F has nanostructures 109F that are like the nanostructures 109A of FIG. 1 except that the nanostructures 109F are formed in a layer 601 disposed over the back side 137. The layer 601 is an optical material with a refractive index distinct from that of the optical material layer 111. The layer 601 may have either a greater or a lesser refractive index that the optical material layer 111. Optionally, the optical material layer 111 is eliminated altogether so that the contrasting medium is air. If the layer 601 is over rather than under the optical material layer 111, the pattern of the nanostructures 109F may be reversed, e.g., from spacing that progressively decreases with distance from the center 102 to spacing that progressively increases with distance from the center 102.

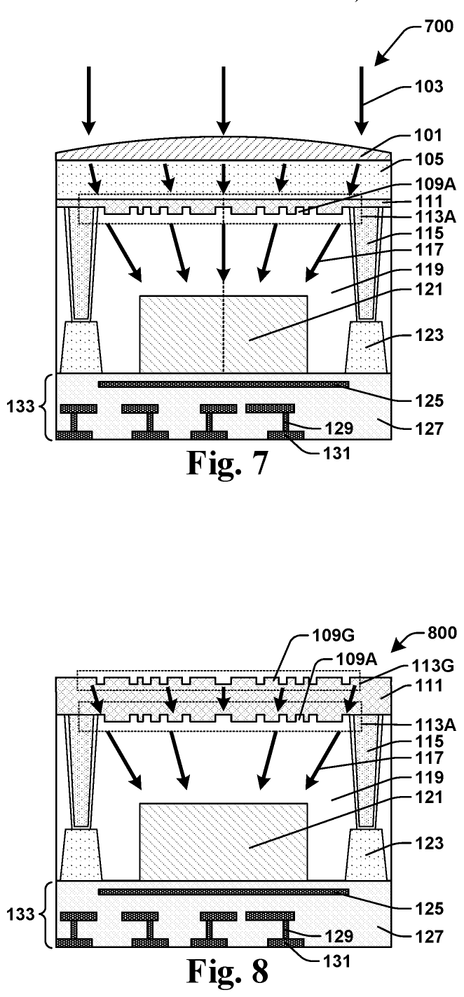

FIG. 7 illustrates a cross-sectional view of an image sensing device 700 according to another embodiment. The image sensing device 700 is like the image sensing device 100 of FIG. 1 except that the image sensing device 700 has a microlens 101 disposed over the metalens 113A. The microlens 101 and the metalens 113A combine to provide a desired focal length. A spacer 105 of an optical material may be disposed between the microlens 101 and the metalens 113A. In some embodiments, the spacer 105 is a wavelength filter. In some embodiments, the spacer 105 is integral with the optical material layer 111 that fills in gaps between the nanostructures 109A of the metalens 113A.

FIG. 8 illustrates a cross-sectional view of an image sensing device 800 according to another embodiment. The image sensing device 800 is like the image sensing device 100 of FIG. 1 except that the image sensing device 800 has a second metalens 113G in series with the metalens 113A. The metalens 113A and the second metalens 113G combine to provide the desired focal length. The second metalens 113G may have nanostructures 109G that are formed in an upper surface of the optical material layer 111. In some embodiments, the nanostructures 109G are formed in a separate layer disposed over the optical material layer 111. The nanostructures 109G may have the same pattern as the nanostructures 109A, or a different pattern.

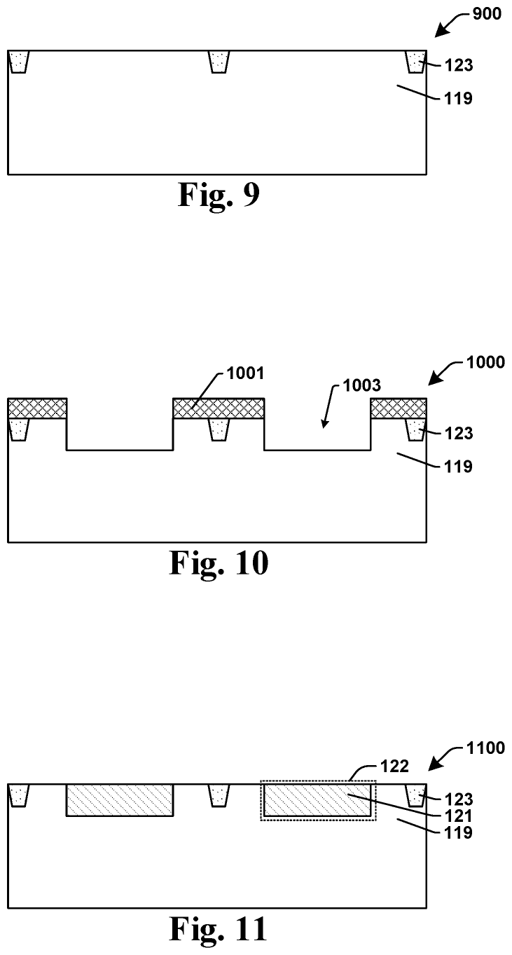

FIGS. 9 through 22 illustrate cross-sectional views exemplifying a method according to the present disclosure of forming an image sensing device. While FIGS. 9 through 22 are described with reference to various embodiments of a method, it will be appreciated that the structures shown in FIGS. 9 through 22 are not limited to the method but rather may stand alone separate from the method. FIGS. 9 through 22 are described as a series of acts. The order of these acts may be altered in other embodiments. While FIGS. 9 through 22 illustrate and describe a specific set of acts, some may be omitted in other embodiments. Further, acts that are not illustrated and/or described may be included in other embodiments.

As illustrated by the cross-sectional view 900 of FIG. 9, the method may begin with forming shallow trench isolation structures 123 in the semiconductor body 119. The semiconductor body may be a bulk semiconductor substrate or the upper layer of a semiconductor on insulator substrate or the like. The semiconductor body 119 may be silicon (Si), the like, or some other semiconductor. The shallow trench isolation structures 123 may be formed by etching trenches in the semiconductor body 119 and filling the trenches with a dielectric such as silicon dioxide (SiO₂), the like, or some other semiconductor. The shallow trench isolation structures 123 are parts of structures for creating isolation between adjacent photodetecting regions 122. Any suitable isolation strategy may be used. Accordingly, the shallow trench isolation structures 123 are optional.

As illustrated by the cross-sectional view 1000 of FIG. 10, a mask 1001 may be formed and used to etch trenches 1003 in the semiconductor body 119. After etching, the mask 1001 may be stripped. As illustrated by the cross-sectional view 1100 of FIG. 11, the trenches 1003 may be filled with a second semiconductor to form the photosensitive structures 121. The second semiconductor has a distinct composition from the semiconductor body 119. In some embodiments, the second semiconductor is germanium (Ge) or the like. The trenches 1003 may be filled with the second semiconductor by epitaxial growth, the like, or some other suitable process. Excess semiconductor may be removed by a planarization process such as chemical mechanical polishing (CMP) or the like.

Additional processing (not illustrated) may take place to form photodetecting regions 122 that include the photosensitive structures 121. Such additional processing may include masking, doping, and deposition and patterning of a gate stack. The additional processing may form such structures as floating diffusion regions, transfer gates, PN diodes, the like, and other structures related to functioning of the photodetecting regions 122. In some embodiments, the additional processing includes the formation of PN diodes (not shown) within the photosensitive structures 121. The PN diodes may alternatively be formed within the semiconductor body 119. In this regard, it should be appreciated that the photosensitive structures 121 may be the photosensitive areas of any type of photodetectors.

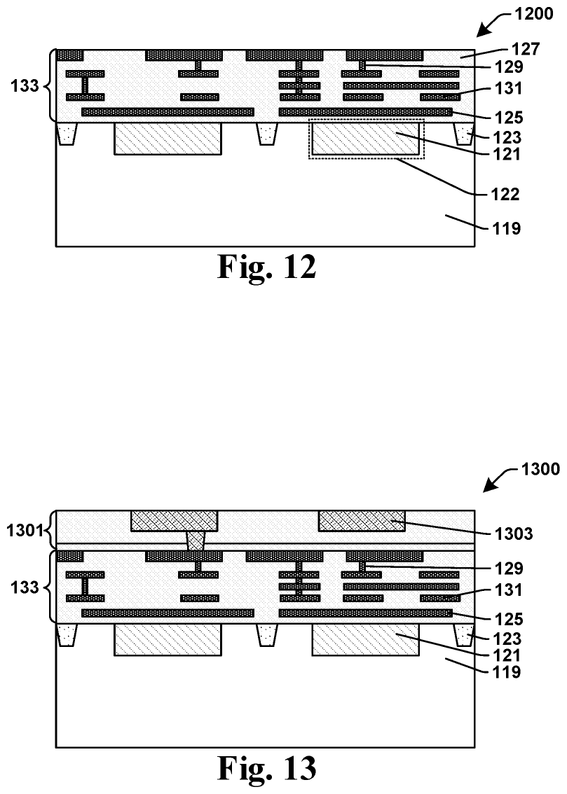

As illustrated by the cross-sectional view 1200 of FIG. 12, a metal interconnect 133 may be formed over the semiconductor body 119. The metal interconnect 133 includes wires 131 and vias 129 that may form electrical connections to the photodetecting regions 122. The wires 131 and the vias 129 may be metal, the like, or any other suitable conductive material. The wires 131 and the vias 129 may be surrounded by interlevel dielectric 127. Reflectors 125 may also be formed within the metal interconnect 133. The interlevel dielectric 127 may be silicon dioxide (SiO₂), a low k dielectric, the like, or any other suitable dielectric material. The metal interconnect 133 may be formed through a series of damascene or dual damascene processes, the like, or by any other suitable method.

As illustrated by the cross-sectional view 1300 of FIG. 13, a bonding structure 1301 may be formed over the metal interconnect 133. The bonding structure 1301 may include bond pads 1303 that are electrically coupled to wires 131.

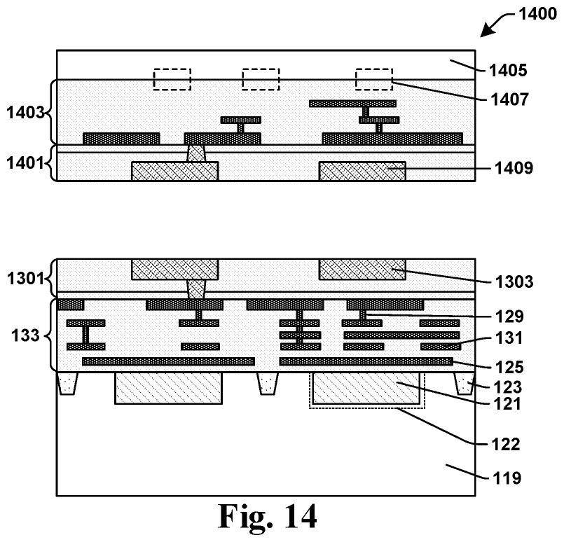

As illustrated by the cross-sectional view 1400 of FIG. 14, a second substrate 1405 may be aligned to the structure shown by the cross-sectional view 1300 of FIG. 13. A metal interconnect 1403 and a bonding structure 1401 may be formed over the second substrate 1405. Transistors 1407 and other such structures may be formed in the second substrate 1405. These transistors may provide select gates, erase gates, the like, and other such structures that make the photodetecting regions 122 operative in an image sensing device. The bonding structure 1401 may include bond pads 1409.

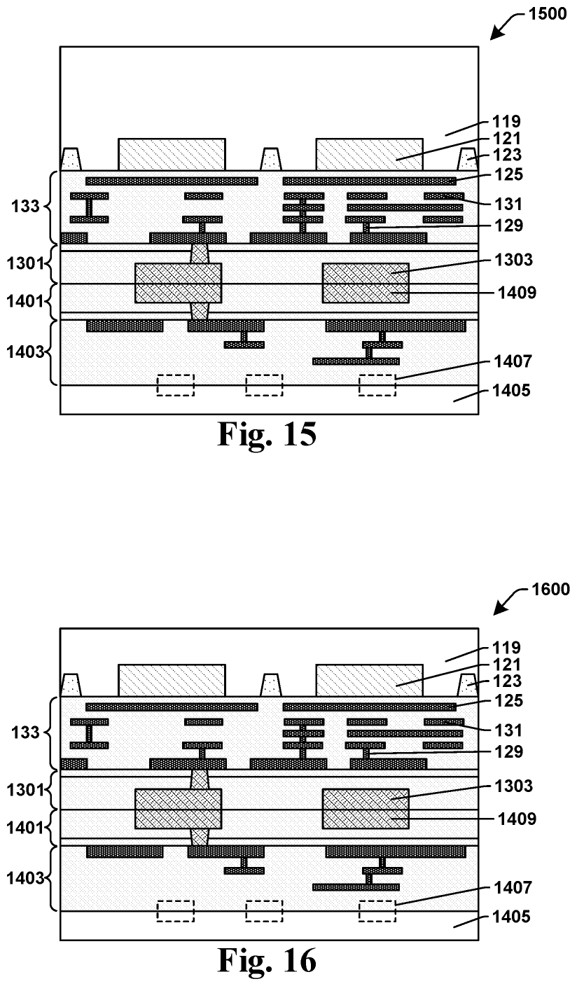

As illustrated by the cross-sectional view 1500 of FIG. 15, the semiconductor body 119 may be joined to the second substrate 1405 through a bonding process. The bonding process may be oxide-to-oxide bonding, metallic bonding, a combination thereof, the like, or any other suitable bonding process. Electrical connections may be formed between the bond pads 1303 and the bond pads 1409.

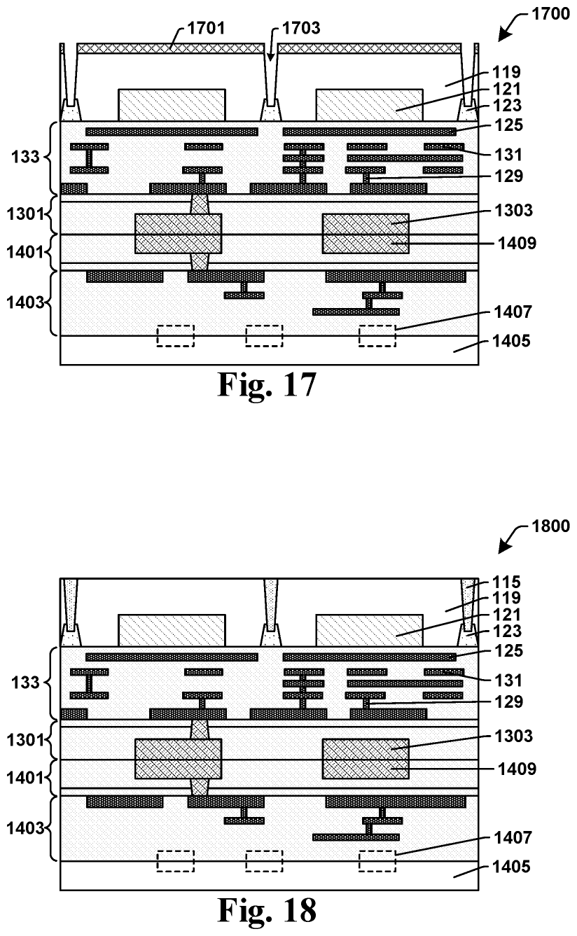

As illustrated by the cross-sectional view 1600 of FIG. 16, the structure illustrated by the cross-sectional view 1500 of FIG. 15 may be flipped and the semiconductor body 119 may be thinned. The thinning process may be CMP, the like, or any other suitable process.

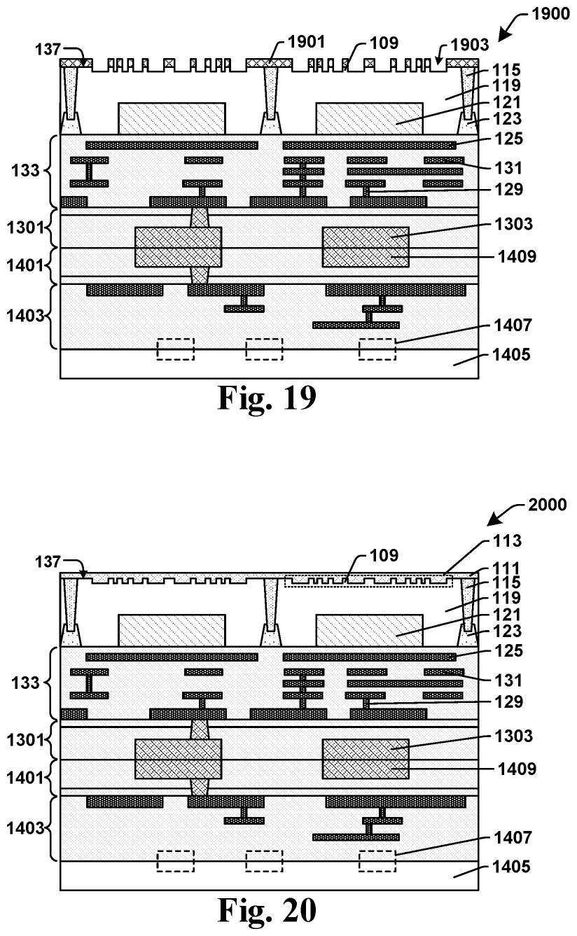

As illustrated by the cross-sectional view 1700 of FIG. 17, a mask 1701 may be formed and used to etch trenches 1703 in the semiconductor body 119. After etching, the mask 1701 may be stripped. As illustrated by the cross-sectional view 1800 of FIG. 18, the trenches 1703 may be filled with dielectric material to for back side deep trench isolation structures 115. The dielectric material may include one or more layers of dielectrics such hafnium oxide (HfO), aluminum oxide (AlO), tantalum oxide (Ta₂O₃), silicon oxide (SiO₂), the like, or any other suitable materials. The dielectrics may be deposited by chemical vapor deposition (CVD), physical vapor deposition (PVD), atomic layer deposition (ALD), the like, or any other suitable processes. Excess dielectric may be removed by a planarization process such as chemical mechanical polishing (CMP) or the like.

As illustrated by the cross-sectional view 1900 of FIG. 19, a mask 1901 may be formed and used to etch trenches 1903 in the back side 137 of the semiconductor body 119. The etch process forms the nanostructures 109 in the back side 137. The mask 1901 may be a photoresist, a hard mask, or any other suitable type of mask. The mask 1901 may be patterned by photolithography, electron-beam lithography, the like, or any other type of patterning process. The etch process may be a dry etch, a wet etch, or the like. A dry etch process may be plasma etching or the like. In some embodiments, the etch conditions are selected so that the trenches 1903 all have approximately equal depths. After etching, the mask 1901 may be stripped.

As illustrated by the cross-sectional view 2000 of FIG. 20, the optical material layer 111 may be deposited over the back side 137 so as to fill spaces between the trenches 1903 between the nanostructures 109. The optical material layer 111 may be deposited by CVD, PVD, ALD, the like, or any other suitable process. Optionally, deposition is followed by a planarization process such as CMP, the like, or any other suitable process. The nanostructures 109 and the optical material layer 111 form the metalens 113. Planarization of the optical material layer 111 may be used to improve the focus of the metalens 113.

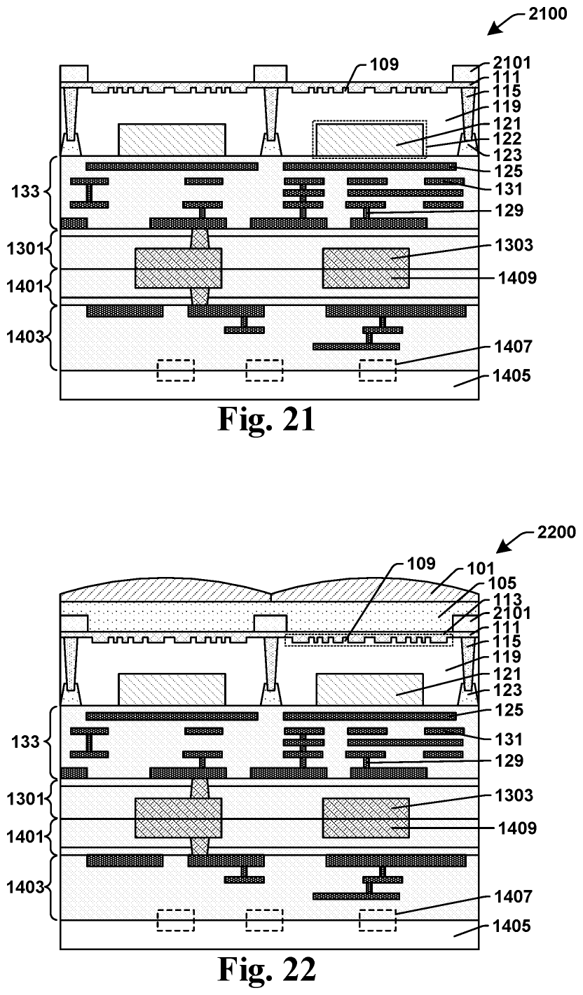

As illustrated by the cross-sectional view 2100 of FIG. 21, a back side metal grid 2101 may be formed over the optical material layer 111. The back side metal grid 2101 may reduce crosstalk between adjacent photodetecting regions 122. The back side metal grid 2101 may be formed by depositing a layer of a metal or other suitable material followed by forming a mask and etching to pattern the layer.

As illustrated by the cross-sectional view 2200 of FIG. 22, the spacers 105 and microlenses 101 may be formed over the optical material layer 111. The spacers 105 may be deposited by CVD, PVD, ALD, the like, or any other suitable process. Microlens 101 may be formed of dielectric, polymer, the like, or any other suitable material and may be formed by any suitable process. The process of forming the mircolenses may include, for example, deposition of the lens material followed by etching to define the lens shapes. In some embodiments, the formation process includes a thermal reflow process or the like.

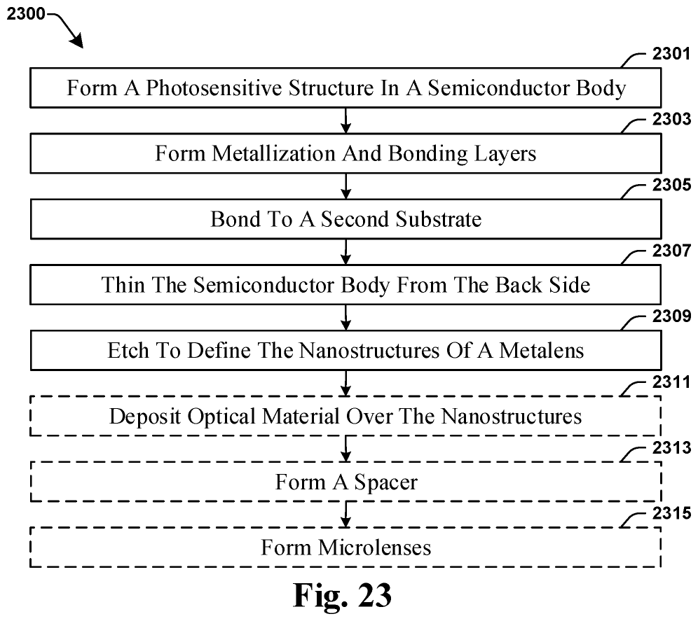

FIG. 23 presents a flow chart for a process 2300 that may be used to form an image sensing device according to the present disclosure. While the process 2300 of FIG. 23 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts are required to implement one or more aspects or embodiments of the description herein, and one or more of the acts depicted herein may be carried out in one or more separate acts and/or phases.

The process 2300 may begin with act 2301, forming a photosensitive structure in a semiconductor body. The photosensitive structure may be any type of photosensitive structure. In some embodiments, the photosensitive structure is germanium (Ge) and provides a germanium sensor. The cross-sectional views 900-1100 of FIGS. 9-11 provide an example.

The process 2300 may continue with act 2303, forming metallization and bonding layers over the semiconductor body. The cross-sectional views 1200-1300 of FIGS. 12-13 provide an example. A metalens according to the present disclosure may be used for image sensing devices having either front side or back side illumination. In some embodiments, the image sensing device is of the type that uses back side illumination. Formation of the bonding layer and attachment to a second substrate are steps in a process of forming a device that uses back side illumination.

Act 2305 is bonding the semiconductor body to a second substrate through the bonding layer. The cross-sectional views 1400-1500 of FIGS. 14-15 provide an example. Act 2307 is thinning the semiconductor body from the back side. The cross-sectional view 1600 of FIG. 16 provides an example. Thinning the semiconductor body may bring the back side to within a few microns, e.g., to within about 4 to about 10 microns of the front side.

Act 2309 is etching the back side to define the nanostructures of a metalens. The cross-sectional view 1900 of FIG. 19 provides an example. In an alternative embodiment, a layer of a second optical material is deposited over the back side and the nanostructures of the metalens are formed in that layer.

Act 2311 is an optional act of depositing a layer of optical material over the nanostructures. The cross-sectional view 2000 of FIG. 20 provides an example. The layer of optical material fills gaps between the nanostructures and may serve other function such as reducing reflections and providing electrical isolation for the semiconductor body.

Act 2313 is another optional act, forming a spacer layer over the nanostructures. In some embodiments, the spacer layer comprises a wavelength filter. If a spacer layer is employed, it may be thinner than the spacer layer that would be used in the absence of the metalens.

Act 2315 is another optional act, forming a microlens over the spacer layer. The cross-sectional view 2100 of FIG. 21 provides an example. The microlens and the metalens together may provide a shorter focal length than could be provided with either type of lens by itself.

Some aspects of the present disclosure relate to an image sensing device that includes a photosensitive structure within a semiconductor body. A metalens that focuses electromagnetic radiation on the photosensitive structure is on the back side of the semiconductor body. In some embodiment, the metalens comprises nanostructures formed in the back side. In some embodiments, the nanostructures are concentric rings. In some embodiments, the nanostructures protrude into a film of optical material that is on the back side. In some embodiments, the nanostructures have spacings that vary in relation to distance from a center of the photosensitive structure. In some embodiments, the metalens comprises an arrangement of pillars of an optical material protruding into the semiconductor body. In some embodiments, the metalens comprises nanostructures having heights that vary in systematic relationship to distance from a center of the photosensitive structure. In some embodiments, the metalens comprises nanostructures structures that achieve a focusing effect through variations in two or more of depth, spacing, or size. In some embodiments, there is a microlens over the metalens. In some embodiments, the metalens at least doubles a concentration of infrared light on the photosensitive structure with respect to infrared light with perpendicular incidence on the back side. In some embodiments, the metalens comprises nanostructures that have a pattern of variation that repeats at least twice over a length of increasing distance from a center of the metalens.

Some aspects of the present disclosure relate to an image sensing device that includes a semiconductor body comprising a front side and a back side. The semiconductor body has a first refractive index. An optical material is disposed on the back side. The optical material has a second refractive index that is distinct from the first refractive index. A photodetecting region comprising a photosensitive structure is disposed within the semiconductor body. A metalens formed by the optical material and the semiconductor body focuses near infrared light on the photosensitive structure. In some embodiments, the photosensitive structure comprises a second semiconductor having a composition distinct from the semiconductor body. In some embodiments, the semiconductor body is silicon and the photosensitive structure is germanium.

Some aspects of the present disclosure relate to a method of manufacturing an image sensing device. The method includes providing a semiconductor body, forming a photosensitive structure in the semiconductor body, and patterning a back side of the semiconductor body to form nanostructures that comprise a metalens. The nanostructures are configured so that the metalens focuses electromagnetic radiation having a wavelength in the infrared range on the photosensitive structure. In some embodiments, forming the photosensitive structure in the semiconductor body comprises etching a trench in the semiconductor body and filling the trench with a second semiconductor. In some embodiments, the method further includes depositing an optical material over the nanostructures. The optical material fills spaces between the nanostructures. In some embodiments, the method includes forming a microlens over the metalens. In some embodiments, the photosensitive structure is a germanium sensor comprising a germanium structure and the metalens focuses the electromagnetic radiation having the wavelength in the infrared range on the germanium structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensing device, comprising:
a semiconductor body having a first side and a second side;
a photodetecting region comprising a photosensitive structure within the semiconductor body; and
a metalens disposed on or at the second side, wherein the metalens is configured to focus electromagnetic radiation on the photosensitive structure.

2. The image sensing device of claim 1, wherein the metalens comprises nanostructures formed in the second side of the semiconductor body.

3. The image sensing device of claim 2, wherein the nanostructures are concentric rings.

4. The image sensing device of claim 2, wherein the nanostructures protrude into a film of optical material on the second side.

5. The image sensing device of claim 2, wherein the nanostructures have spacings that vary in relation to distance from a center of the photosensitive structure.

6. The image sensing device of claim 1, wherein the metalens comprises an arrangement of pillars of an optical material protruding into the semiconductor body from the second side.

7. The image sensing device of claim 1, wherein the metalens comprises nanostructures having heights that vary in systematic relationship to distance from a center of the photosensitive structure.

8. The image sensing device of claim 7, wherein the nanostructures are formed by the semiconductor body.

9. The image sensing device of claim 1, wherein the metalens comprises nanostructures structures that achieve a focusing effect through variations in two or more of depth, spacing, or size.

10. The image sensing device of claim 1, further comprising a microlens over the metalens.

11. The image sensing device of claim 1, wherein the metalens at least doubles a concentration of infrared light on the photosensitive structure with respect to infrared light with perpendicular incidence on the second side.

12. The image sensing device of claim 1, wherein the metalens comprises nanostructures that have a pattern of variation that repeats at least twice over a length of increasing distance from a center of the metalens.

13. An image sensing device, comprising:
a semiconductor body comprising a first side and a second side, wherein the semiconductor body has a first refractive index;
an optical material disposed on the second side, wherein the optical material has a second refractive index which is distinct from the first refractive index;
a photodetecting region comprising a photosensitive structure disposed within the semiconductor body; and
a metalens formed by the optical material and the semiconductor body, wherein the metalens is structured to focus near infrared light on the photosensitive structure.

14. The image sensing device of claim 13, wherein the photosensitive structure comprises a second semiconductor having a composition distinct from the semiconductor body.

15. The image sensing device of claim 13, wherein the semiconductor body is silicon and the photosensitive structure is germanium.

16. A method comprising:
providing a semiconductor body having a first side and a second side;
forming a photodetecting region comprising a photosensitive structure in the semiconductor body; and
patterning the second side of the semiconductor body to form nanostructures comprising a metalens, wherein the nanostructures are configured so that the metalens focuses electromagnetic radiation having a wavelength in the infrared range on the photosensitive structure.

17. The method of claim 16, wherein forming the photodetecting region in the semiconductor body comprises etching a trench in the semiconductor body and filling the trench with a second semiconductor.

18. The method of claim 16, further comprising depositing an optical material over the nanostructures, wherein the optical material fills spaces between the nanostructures.

19. The method of claim 16, further comprising forming a microlens over the metalens.

20. The method of claim 16, wherein the photosensitive structure is germanium and the metalens focuses the electromagnetic radiation having the wavelength in the infrared range on the photosensitive structure.
